(19) United States
(12) Patent Application Publication
(10) Pub. No.: US 2007/0071145 A1
(43) Pub. Date: Mar. 29, 2007

(54) Method and apparatus to correct channel quality indicator estimation

(76) Inventor: Yona Perets, Ra'anana (IL)

Correspondence Address: PEARL COHEN ZEDEK LATZER, LLP, 1500 BROADWAY, 12TH FLOOR, NEW YORK, NY, 10036, US

(21) Appl. No.: 11/232,970

(22) Filed: Sep. 23, 2005

(51) Int. Cl. H03D 1/04

(52) U.S. Cl. 375/346

(57) ABSTRACT

Embodiments of the present invention provide a method and apparatus to correct channel quality indicator estimation with advanced receivers. Demonstrative embodiments of the invention include a receiver having an estimator to estimate a channel quality indicator value of a channel according to one or more estimated base values and a correction value, wherein said estimated base values correspond to one or more parameters of a received reference signal, and said correction value corresponds to a comparison between at least one of said reference signal parameters and at least one parameter relating to a received data signal. Additional features are described and claimed.

### BACKGROUND OF THE INVENTION

Third generation (3G) cellular networks such as, for example, Wideband Code Division Multiple Access (WCDMA), are evolving to provide high speed packet switched data for cellular subscribers. For example, in WCDMA 3GPP Release 5, the Third Generation Partnership Project (3GPP) standard defines new protocols and new physical channels for the High Speed Downlink Packet Access (HSDPA) concept, which may be able to provide data rates up to approximately 10 Mbps or higher to support packet-based multimedia services over a 5 MHz bandwidth in WCDMA downlink. HSDPA implementations may include Adaptive Modulation and Coding (AMC), Hybrid Automatic Request (HARQ), fast cell search, fast scheduling, and advanced receiver design.

Advanced receivers may utilize sophisticated AMC and scheduling mechanisms, e.g., those incorporated in Release 5 of the WCDMA standard. For example, demodulation of a received HSDPA signal in advanced receivers may no longer be rake-based, as is the demodulation in rake receivers commonly found in the art. The AMC and scheduling mechanisms depend on the user equipment, e.g., handset, being able to measure and report back to the base station a Channel Quality Indicator (CQI) value, which may be estimated based on a reference Common Pilot Channel (CPICH), as it is known in the art In an advanced receiver, channel quality may be higher than that of, for example, a rake-based receiver, and improvement in channel quality is taken into account in the reported CQI.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features and advantages thereof, may best be understood by reference to the following detailed description when read with the accompanied drawings in which:

FIG. 1 is a simplified illustration of a wireless communication system according to one demonstrative embodiment of the present invention;

FIG. 2 is a simplified block diagram of part of a communication device incorporating CQI estimation according to one demonstrative embodiment of the present invention; and

FIG. 3 is a more detailed schematic illustration of part of a communication device incorporating CQI estimation according to another demonstrative embodiment of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following detailed description, numerous specific details are set forth in order to provide a thorough understanding of the invention. However, it will be understood by those of ordinary skill in the art that the present invention may be practiced without these specific details. In other instances, well-known methods, procedures, components and circuits have not been described in detail so as not to obscure the present invention.

Some portions of the detailed description, which follow, are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

It should be appreciated that according to some embodiments of the present invention, the method described below, may be implemented in machine-executable instructions. These instructions may be used to cause a general-purpose or special-purpose processor that is programmed with the instructions to perform the operations described. Alternatively, the operations may be performed by specific hardware that may contain hardwired logic for performing the operations, or by any combination of programmed computer components and custom hardware components.

Although the scope of the present invention is not limited in this respect, the system and method disclosed herein may be implemented in many wireless, handheld and portable communication devices such as, for example, modems, wireless local area network (WLAN) stations, receivers of a radio system or the like. By way of example, wireless, handheld and portable communication devices may include wireless and cellular telephones, smart telephones, personal digital assistants (PDAs), web-tablets and any device that may provide wireless access to a network such, an intranet or the Internet. It should be understood that the present invention may be used in a variety of applications.

Types of cellular radiotelephone receivers intended to be within the scope of the present invention may include, but are not limited to, Code Division Multiple Access (CDMA), CDMA-2000 and wideband CDMA (WCDMA) cellular radiotelephone receivers for receiving spread spectrum signals, Global System for Mobile communication (GSM) cellular radiotelephone, General Packet Radio Service (GPRS), Extended GPRS (EGPRS), third generation cellular systems (3G), and the like. For simplicity, although the scope of the invention is in no way limited in this respect, embodiments of the invention described below may be related to a CDMA family of cellular radiotelephone systems that may include CDMA, WCDMA, CDMA 2000 and the like.

The term “plurality” may be used throughout the specification to describe two or more components, devices, elements, parameters and the like. For example, “plurality of mobile stations” describes two or more mobile stations. In addition, it should be known to one skilled in the art that the term “a portable communication device” may refer to, but is not limited to, a mobile station, a portable radiotelephone device, a cell-phone, a cellular device, personal computer, personal digital assistant (PDA), user equipment and the like.

Some demonstrative embodiments of the invention include a method, apparatus, and/or system to correct channel quality indicator (CQI) estimation with advanced receivers, as described in detail below.

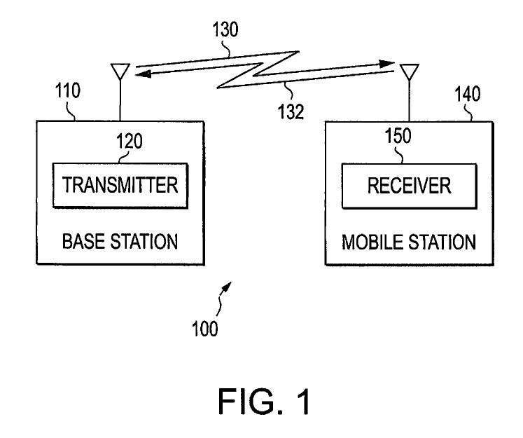

Reference is made to FIG. 1, which schematically illustrates a wireless communication system 100 including one or more stations capable of estimating and reporting CQI according to a demonstrative embodiment of the present invention.

Although the scope of the present invention is not limited to this example, wireless communication system 100 may include at least one base station 110 and at least one mobile station 140. In some embodiments of the invention, base station 110 may include a transmitter 120 to transmit signals and mobile station 140 may include a receiver 150 to receive signals. In some embodiments of the invention, transmitter 120 and receiver 150 may be implemented as a transceiver, a transmitter-receiver, a wireless modem, or one or more units able to perform separate or integrated functions of sending and/or receiving wireless communication signals, blocks, frames, data items, transmission streams, packets, messages, and/or data. The architectures of transmitter 120 and receiver 150 may be suitable for WCDMA communication systems, although the scope of the present invention is not limited in this respect.

Further, wireless communication system 100 may include one or more wireless communication links, e.g., a downlink 130 and an uplink 132, to transfer communications between base station 110 and mobile station 140 For example, downlink 130 may transfer data communications from base station 110 to mobile station 140 while uplink 132 may transfer data communications from mobile station 140 to base station 110 In some embodiments of the invention, links 130 and 132 may include one or more sub-channels, which may be used for voice and/or data transportation. Furthermore, the sub-channels may include a plurality of sub-carriers to carry signals, for example, pilot signals, coded signals, data signals, control signals, or the like. The sub-channels may include, e.g., HSPDA data channels and/or pilot reference channels.

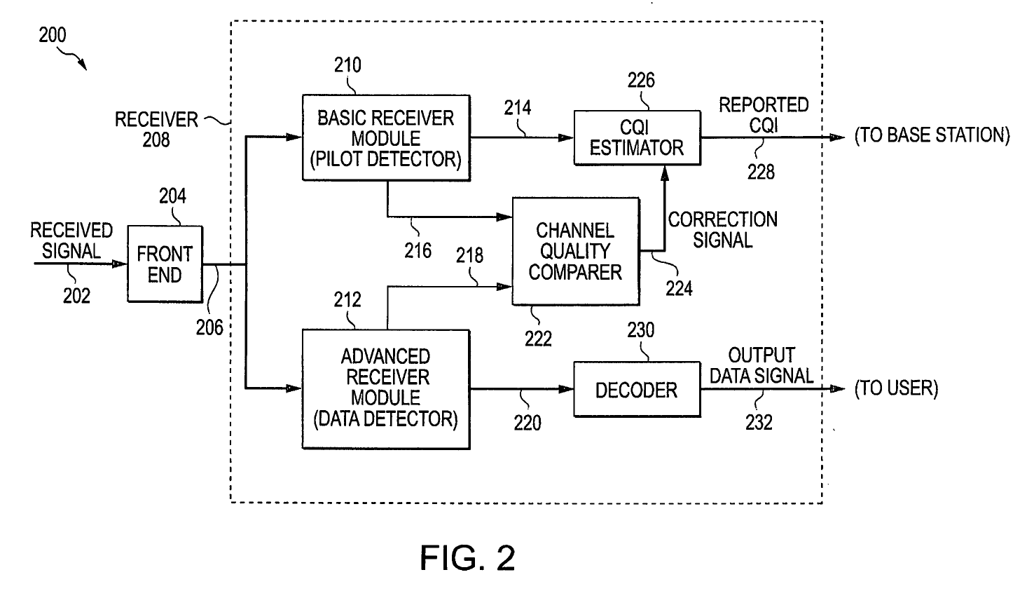

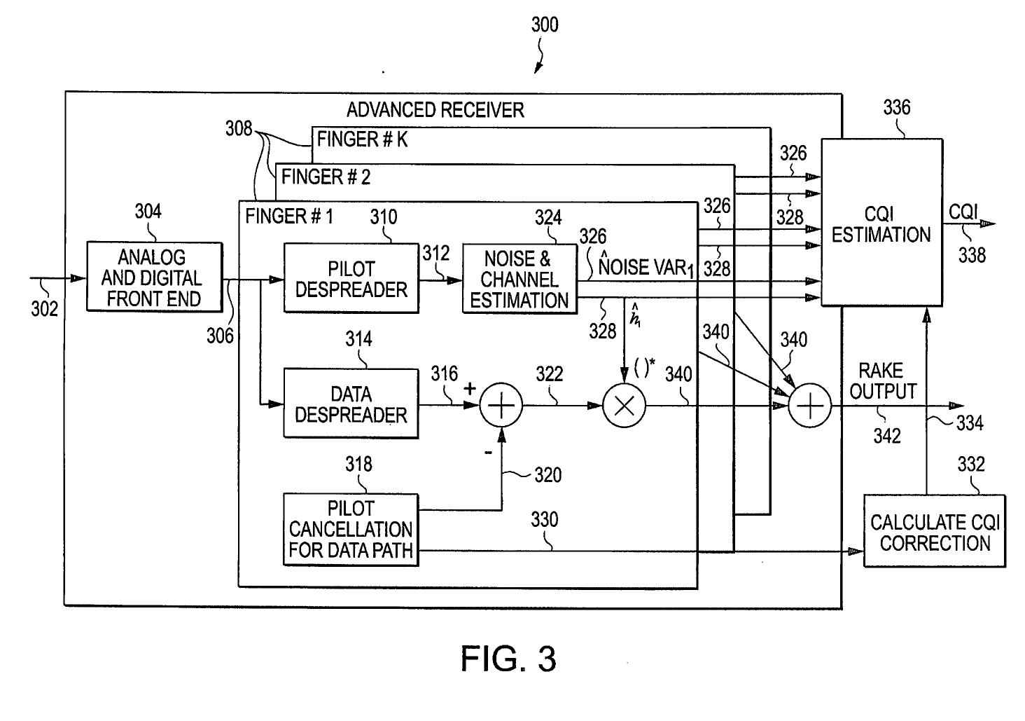

According to some demonstrative examples of the present invention, base station 110 may transfer communications to mobile station 140 via downlink 130, including, for example, pilot signals on a pilot channel and/or data signals on a HSPDA channel. Although the invention is not limited in this respect, receiver 150 may be an advanced receiver, such as, for example, a pilot cancellation receiver, a multi-path interference cancellation receiver, or a chip rate equalizer receiver, e.g., a minimum mean square error (MMSE) estimation receiver. An embodiment of the invention including a pilot cancellation receiver is described below with reference to FIG. 3. In accordance with embodiments of the invention, receiver 150 may be able to, for example, estimate a channel quality indicator (CQI) for a HSPDA channel with reference to a pilot channel and other parameters relating to the advanced receiver technology, as described below with reference to FIG. 2.

Although the invention is not limited in this respect, mobile station 140 may transmit a reported CQI signal back to the base station via uplink 132. Base station 110 may estimate, for example, the channel quality of each active HSDPA user, based on the reported CQI feedback and other parameters from mobile station 140, e.g, buffer status, priority, user equipment capabilities, or the like. According to the channel quality, the base station may decide on a new modulation and coding scheme to maximize user throughput.

Reference is made to FIG. 2, which schematically illustrates part of a communication device incorporating CQI estimation according to some demonstrative embodiments of the invention. Although the invention is not limited in this respect, communication device 200 may include an analog and digital front end 204 and a receiver 208, which may be an advanced receiver. Receiver 208 may include a basic receiver module 210 and an advanced receiver module 212, a channel quality comparer 222, a CQI estimator 226, and a decoder 230, e.g., an HSDPA decoder. According to some demonstrative embodiments of the invention, elements of receiver 208 may be implemented as components of the same entity and/or as components of separate entities. For example, components of communication device 200 may correspond to one or more components of mobile unit 140 and/or receiver 150 of FIG. 1.

According to some demonstrative embodiments of the invention, a received signal 202, e.g., a radio signal received via an antenna, may pass through front end 204 and be converted to a digital base-band signal. For example, front end 204 may act on received signal 202 according to techniques known in the art, including, e.g., filtering interference, amplifying, down-converting, and converting to digital domain. Digital signal 206 may include pilot symbols and data symbols. Although the invention is not limited in this respect, basic receiver module 210 may detect pilot symbols from signal 206, and advanced receiver module 212 may detect data symbols 220 from signal 206. Decoder 230 may decode data information from data symbols 220 to produce an output data signal 232 with data information that may be transmitted to a user. Although the invention is not limited in this respect, advanced module 212 may be a data detection module and may provide, for example, pilot cancellation, multi-path interference cancellation, or chip rate equalization e.g., using MMSE estimation, and may allow a higher throughput of data symbols due to, for example, an improved signal-to-noise ratio (SNR) of the data signal.

According to some demonstrative embodiments of the invention, basic receiver module 210 may be able to measure an estimated channel quality parameter value based on the pilot signal for use in CQI estimation according to techniques known in the art For example, a pilot estimation signal 214 may be sent to CQI estimator 226 and may contain estimated parameter values such as, for example, a channel estimation value, symbolized hˆ in the art, which may reflect the channel phase and gain of the received pilot signal, and a noise variance estimation value, which may represent the associated noise power of the received pilot signal. Although the invention is not limited in this respect, basic receiver module 210 may send a basic receiver module estimation signal 216 to channel quality comparer 222 to provide information for calculating channel quality of a receiver equipped with basic components, including, for example, the channel estimation value hˆ. For example, basic module estimation signal 216 may include part of the information contained in pilot estimation signal 214.

In addition, comparer 222 may receive an advanced receiver module estimation signal 218, e.g., a data estimation signal, from advanced receiver module 212, which signal may include information for calculating channel quality of a receiver equipped with an advanced module, including, for example, a channel estimation value or parameters relating to the advanced receiver technology. For example, receiver 208 may be a pilot cancellation based receiver and estimation signal 218 may contain parameter values relating to channel estimation, selection of cancelled paths, and combined filter response. As another example, receiver 208 may be a MMSE based chip rate equalization receiver, and estimation signal 218 may contain parameter values relating to the MMSE filter taps, which may vary over time Equations relating to the advanced receiver technology and corresponding data estimation signal 218 are described in detail below

According to some demonstrative embodiments of the invention, comparer 222 may perform a comparison between estimation signals 216 and 218 to derive a correction signal 224, which may represent the effect of advanced module 212 on channel quality in terms of, for example, SNR of the data signal. Although the invention is not limited in this respect, CQI estimator 226 may derive a channel quality indicator value based on an estimated channel quality parameter value related to the pilot signal, included in pilot estimation signal 214, and a correction value corresponding to the effect of advanced receiver module 212 on the data signal, included in correction signal 224. According to different demonstrative embodiments of the invention, channel quality comparer 222 may be implemented by components within CQI estimator 226 or by components of a separate module within receiver 208. CQI estimator 226 may generate a reported CQI signal 228 to be transmitted to the base station.

Reference is made to FIG. 3, which illustrates part of a communication device incorporating CQI estimation with a pilot cancellation receiver 300 according to another demonstrative embodiment of the invention. Although the invention is not limited in this respect, pilot cancellation receiver 300 may correspond to receiver 208 of FIG. 2.

In accordance with embodiments of the invention, pilot cancellation receiver 300 may be an advanced design of a rake-based receiver, as known in the art, and may include a plurality of rake fingers 308. As described above with reference to FIG. 2, a received signal 302 (202) may be processed by an analog and digital front end 304 (204) to be transformed into a digital signal 306 (206). Digital signal 306 may be, for example, a spread-spectrum signal encoded according to Code Division Multiple Access (CDMA), as known in the art, and may carry, for example, pilot symbols and data symbols Active rake fingers 308 may include a pilot despreader 310 to despread signal 306 and detect pilot symbols, and a data despreader 314 to despread signal 306 and detect data symbols 316.

In addition, according to some demonstrative embodiments of the invention, active rake fingers 308 may include a pilot cancellation module 318, which may, for example, detect interference from pilot signals of neighboring stations. Pilot cancellation module 318 may produce a pilot interference cancellation signal 320, which may be added to data signal 316 to produce a data signal 322 with a higher signal-to-noise ratio. In addition, pilot cancellation module 318 may transmit a pilot cancellation estimation signal 330 (218), relating to the pilot cancellation algorithm, to a CQI correction calculator 332 (222). As explained above with reference to FIG. 2, correction calculator 332 may derive a CQI correction signal 334 to represent the effect of the pilot cancellation algorithm on the received data signal, that is, to represent the differences between data signal 316 and data signal 322, e.g., in terms of SNR.

Pilot cancellation receiver 300 may include, e.g., for each, or at least some of, active rake fingers 308, a noise and channel estimation module 324 to estimate channel quality parameter values from pilot signal 312, including, for example, a noise variance value 326 and a channel estimation value, hˆ, 328. Although the invention is not limited in this respect, pilot estimation values in signals 326 and 328 may correspond to values contained in pilot estimation signal 214 of FIG. 2. For each, or at least some of, active rake fingers 308, pilot estimation values in signals 326 and 328 may be sent to a CQI estimator 336 (226). As explained above with reference to FIG. 2, estimator 336 may derive a CQI value 338 (228) based on the estimated channel quality parameter values in pilot estimation signals 326 and 328, and correction signal 334.

It will be appreciated by those with skill in the art that pilot estimation signal 328 may also be used to correct the phase of data signal 322 to produce a rake finger output data signal 340 Output signals 340 from each, or at least some of, active rake fingers 308 may be combined to produce a rake output signal 342 to a user. For example, rake output 342 may be derived from rake finger data signals 322 using, e.g., an Equal Gain Combiner (EGC) or Maximum Ratio Combiner (MRC), as are known in the art.

Although the invention is not limited in this respect, referring back to FIG. 2, the methods utilized by CQI estimator 226 and comparer 222 may be more easily understood with reference to formulas and parameters set out below. For example, CQI may be calculated as a function of channel quality parameters such as, for example, power estimation (Pest) and noise and interference power estimation (Nest), and a CQI correction value (CQI_Correction). Although the invention is not limited in this respect, the following general formula may be applied by processors, e.g., a digital signal processor (DSP), within CQI estimator 226:
CQI=ƒ(Pest,Nest, CQI_Correction) (1)

Although the invention is not limited in this respect, the function ƒ used in CQI estimation may vary according to different demonstrative embodiments of the invention and the specific advanced receiver technology For example, where CQI estimation is implemented for a pilot cancellation based advanced receiver, equation (1) may reduce to the following function:

$$CQI = \frac{Pest}{Nest - CQI\_Correction} \qquad ( 2 )$$

As another example, CQI estimation may be implemented for a MMSE based chip rate equalization receiver and equation (1) may reduce to the following function:

$$CQI = \frac{Pest}{Nest} CQI\_Correstion \qquad ( 3 )$$

According to some demonstrative embodiments of the invention, values relating to Pest and Nest may be estimated, for example, by basic receiver module 210, and included in pilot estimation signal 214. For example, basic receiver module 210 may include components of a rake receiver, e.g., noise and channel estimator 324 of FIG. 3, and pilot estimation signal 214 may include information such as, for example, number of active rake fingers (K), noise variance per rake finger (NoiseVar), and channel estimation taps per rake finger (h). Although the invention is not limited in this respect, the following formulas may be applied:

$$\begin{matrix}Pest = {( {\sum }_{FingerIndex = 1}^{K} {\vert {\hat{h}}_{FingerIndex} \vert}^{2} )}^{2} & ( 4 ) \\ Nest = {\sum }_{FingerIndex = 1}^{K} Noise Var ( FingerIndex ) {\vert {\hat{h}}_{FingerIndex} \vert}^{2} & ( 5 )\end{matrix}$$

According to some demonstrative embodiments of the invention, the CQI correction value may be calculated by processors, e.g., a DSP, within comparer 222 and included in correction signal 224 For example, according to one demonstrative embodiment of the invention, advanced receiver module 212 may provide pilot noise cancellation, as explained above with reference to FIG. 3. Although the invention is not limited in this respect, the following formula may be applied to estimate a correction value corresponding to a cancelled pilot power component:

$$CQI\_Correction \approx \frac{1}{NT \cdot SF} {\sum }_{k = - ∞}^{∞} {\sum }_{i = 1}^{\# RakeFingers} {\sum }_{{j = 1}_{j \neq i}}^{\# Trackers} {\vert {h}_{i} \vert}^{2} \cdot {\vert {h}_{j} \vert}^{2} \cdot ρ ( i , j , k ) - Selection ( i , j , k ) \qquad ( 6 )$$

where:
NT is noise variance, estimated at rake output without pilot cancellation;
SF is a spread factor, i.e., number of chips per data symbol;
h are channel estimation taps;
Selection is a parameter of the pilot cancellation algorithm to indicate which paths j are canceled from rake finger i (0—not cancelled 1—cancelled); and
ρ is a combined filter response, including, e.g., transmit and received filters of a base station and mobile station.

Although the invention is not limited in this respect, channel estimation tap values h may be included in pilot estimation signal 216 and additional parameter values may be included in advanced receiver module estimation signal 218. In addition, some parameter values, for example, values for the combined filter response ρ, may be stored in a fixed table in suitable components of receiver 208.

In another demonstrative embodiment of the invention, advanced receiver module 212 may provide chip rate equalization, for example, using a MMSE estimation model. Although the invention is not limited in this respect, the following formula, for example, may be applied to estimate a correction value corresponding to a ratio between SNR of a chip rate equalizer receiver and SNR of a rake receiver:

$$CQI\_Correction ≅ \frac{{\vert z ( {n}_{0} ) \vert}^{2}}{{\sum }_{n = - ∞ , n \neq {n}_{1}}^{∞} {\vert Z ( n ) \vert}^{2} + {σ}_{i n}^{2} \cdot {\sum }_{n = - ∞}^{∞} {\vert w ( n ) \vert}^{2}} - \frac{{\sum }_{n = - ∞ , n \neq {n}_{1}}^{∞} {\vert U ( n ) \vert}^{2} + {σ}_{i n}^{2} \cdot {\sum }_{n = - ∞}^{∞} {\vert h ( n ) \vert}^{2}}{{\vert U ( {n}_{1} ) \vert}^{2}} \qquad ( 7 )$$

where:
w(n) is a MMSE weight vector;
h(n) is the channel response vector;
Z(n) is the convolution between h(n) and w(n), i.e., Z(n)=h(n)\textcircled{×}w(n);
U(n) is the convolution between h(n) and h*(−n), i.e., U(n)=h(n)\textcircled{×}h* (−n);
n₀ is a MMSE receiver sample time index;
n₁ is a rake receiver sample time index; and
σᵢₙ² is the noise variance at receiver input.

While the invention has been described with respect to a limited number of embodiments, it will be appreciated that many variations, modifications and other applications of the invention may be made. Embodiments of the present invention may include other apparatuses for performing the operations herein. Such apparatuses may integrate the elements discussed, or may comprise alternative components to carry out the same purpose. It will be appreciated by persons skilled in the art that the appended claims are intended to cover all such modifications and changes as fall within the true spirit of the invention.

What is claimed is:

1. An apparatus comprising:
an estimator to estimate a channel quality indicator value of a channel according to one or more estimated base values and a correction value, wherein said estimated base values correspond to one or more parameters of a received reference signal, and said correction value corresponds to a comparison between at least one of said reference signal parameters and at least one parameter relating to a received data signal.

2. The apparatus of claim 1, comprising a comparer to generate a correction signal to provide said correction value based on said comparison.

3. The apparatus of claim 1, comprising an advanced receiver module to provide values of said data signal parameters based on an advanced receiving algorithm.

4. The apparatus of claim 3, wherein said advanced receiving algorithm is to provide pilot interference cancellation.

5. The apparatus of claim 3, wherein said advanced receiving algorithm is to provide chip rate equalization.

6. The apparatus of claim 1, comprising a basic receiver module to estimate said base values from a received reference signal.

7. The apparatus of claim 6, wherein said basic receiver module comprises a rake receiver module.

8. The apparatus of claim 6, wherein said base values comprise a noise variance estimation value of said received reference signal.

9. The apparatus of claim 6, wherein said base values comprise a channel estimation value of said received reference signal.

10. The apparatus of claim 1, wherein said received reference signal is a pilot signal.

11. A method comprising:
estimating a channel quality indicator value of a channel according to one or more estimated base values and a correction value, wherein said estimated base values correspond to one or more parameters of a received reference signal, and said correction value corresponds to a comparison between at least one of said reference signal parameters and at least one parameter relating to a received data signal.

12. The method of claim 11, wherein estimating said estimated base values comprises estimating a pilot signal power value and a pilot signal noise value.

13. The method of claim 12, wherein estimating said channel quality indicator value comprises calculating a ratio between said pilot signal power value and the difference of said pilot signal noise value and said correction value

14. The method of claim 13, wherein comparing said parameter of a received reference signal and said parameter of a received data signal, to produce said correction value, comprises estimating a cancelled pilot power component of said received data signal related to a pilot signal interference cancellation operation.

15. The method of claim 12, wherein estimating said channel quality indicator value comprises calculating a ratio between said pilot signal power value and said pilot signal noise value, and multiplying the result by said correction value.

16. The method of claim 15, wherein comparing said parameter of a received reference signal and said parameter of a received data signal, to produce said correction value, comprises estimating a ratio of symbol signal-to-noise ratios of said received data signal, between a chip rate equalizer receiver and a rake receiver

17. A wireless communication system comprising:
at least one wireless communication device comprising:
a radio frequency antenna to send and receive signals; and
a receiver having an estimator to estimate a channel quality indicator value of a channel according to one or more estimated base values and a correction value, wherein said estimated base values correspond to one or more parameters of a received reference signal, and said correction value corresponds to a comparison between at least one of said reference signal parameters and at least one parameter relating to a received data signal.

18. A wireless communication system according to claim 17, wherein said receiver further comprises a comparer to generate a correction signal to provide said correction value based on said comparison.

19. A wireless communication system according to claim 17, wherein said receiver further comprises an advanced receiver module to provide values of said data signal parameters based on an advanced receiving algorithm.

20. A wireless communication system according to claim 17, wherein said receiver further comprises a basic receiver module to estimate said base values from a received reference signal.

21. A wireless communication system according to claim 17, further comprising an additional wireless communication device to send said reference signal and said data signal over a link of a wireless communication network.

22. A wireless communication system according to claim 17, further comprising an additional wireless communication device to receive said channel quality indicator value over a link of a wireless communication network.
